(19) United States
(12) Patent Application Publication
(10) Pub. No.: US 2025/0029886 A1
(43) Pub. Date: Jan. 23, 2025

(54) SEMICONDUCTOR PACKAGE INCLUDING THERMAL INTERFACIAL MATERIAL PATTERNS

(71) Applicant: SAMSUNG ELECTRONICS CO., LTD., Suwon-si (KR)

(72) Inventors: Myungsam KANG, Suwon-si (KR); Chilwoo KWON, Suwon-si (KR); Hyejin KIM, Suwon-si (KR); Okgyeong PARK, Suwon-si (KR)

(21) Appl. No.: 18/604,875

(22) Filed: Mar. 14, 2024

(30) Foreign Application Priority Data
Jul. 17, 2023 (KR) 10-2023-0092472

(51) Int. Cl. H01L 23/367; H01L 23/00; H01L 23/373; H01L 25/18

(52) U.S. Cl. CPC H01L 23/367; H01L 23/373; H01L 25/18; H01L 24/16; H01L 24/32; H01L 24/73; H01L 2224/16146; H01L 2224/16225; H01L 2224/32225; H01L 2224/73204; H01L 2924/1431; H01L 2924/181

(57) ABSTRACT

A semiconductor package includes: a first semiconductor chip disposed on a package substrate; a second semiconductor chip adjacent to the first semiconductor chip in a horizontal direction and disposed on the package substrate; a plurality of first thermal interfacial material patterns overlapping the first semiconductor chip in a vertical direction; a plurality of second thermal interfacial material patterns overlapping the second semiconductor chip in the vertical direction; and a first non-metal thermal conductive layer disposed between the plurality of first thermal interfacial material patterns, wherein the plurality of first thermal interfacial materials are spaced apart from the plurality of second thermal interfacial materials in the horizontal direction, and a thermal conductivity of the first non-metal thermal conductive layer in the horizontal direction is lower than a thermal conductivity of the first non-metal thermal conductive layer in the vertical direction.

### CROSS-REFERENCE TO RELATED APPLICATION

This application claims priority under 35 U.S.C. § 119 to Korean Patent Application No. 10-2023-0092472, filed on Jul. 17, 2023, in the Korean Intellectual Property Office, the disclosure of which is incorporated by reference herein in its entirety.

### TECHNICAL FIELD

Example embodiments of the present inventive concept relate to a semiconductor package, and more particularly, to a semiconductor package including thermal interfacial material patterns.

### DISCUSSION OF THE RELATED ART

Recently, various semiconductor chips may be packaged in one semiconductor package, and the semiconductor chips are electrically connected to each other and operated as a system. However, an excessive amount of heat may be generated during performance of operations of the semiconductor chips, and due to the excessive amount of heat that is generated from the semiconductor chips, the performance of the semiconductor package may be degraded.

### SUMMARY

According to example embodiments of the present inventive concept, a semiconductor package includes: a first semiconductor chip disposed on a package substrate; a second semiconductor chip adjacent to the first semiconductor chip in a horizontal direction and disposed on the package substrate; a plurality of first thermal interfacial material patterns overlapping the first semiconductor chip in a vertical direction; a plurality of second thermal interfacial material patterns overlapping the second semiconductor chip in the vertical direction; and a first non-metal thermal conductive layer disposed between the plurality of first thermal interfacial material patterns, wherein the plurality of first thermal interfacial materials are spaced apart from the plurality of second thermal interfacial materials in the horizontal direction, and a thermal conductivity of the first non-metal thermal conductive layer in the horizontal direction is lower than a thermal conductivity of the first non-metal thermal conductive layer in the vertical direction.

According to example embodiments of the present inventive concept, a semiconductor package includes: a first semiconductor chip disposed on a package substrate; a second semiconductor chip disposed adjacent to the first semiconductor chip in a horizontal direction; a plurality of first thermal interfacial material patterns overlapping the first semiconductor chip in a vertical direction; a plurality of second thermal interfacial material patterns overlapping the second semiconductor chip in the vertical direction; and a first non-metal thermal conductive layer disposed between the plurality of first thermal interfacial material patterns, wherein the first semiconductor chip includes a first heat source configured to consume first power, and the second semiconductor chip includes a second heat source configured to consume second power that is less than the first power, and a thermal conductivity of the first non-metal thermal conductive layer in the horizontal direction is less than a thermal conductivity of the first non-metal conductive layer in the vertical direction crossing the horizontal direction.

According to example embodiments of the present inventive concept, a semiconductor includes: a package substrate; an interposer substrate disposed on the package substrate; a first semiconductor chip mounted on the interposer substrate; a second semiconductor chip mounted on the interposer substrate and spaced apart from the first semiconductor chip in a horizontal direction; a plurality of first thermal interfacial material patterns overlapping the first semiconductor chip in a vertical direction; a plurality of second thermal interfacial material patterns overlapping the second semiconductor chip in the vertical direction; and a first non-metal thermal conductive layer disposed between the plurality of first thermal interfacial material patterns in the vertical direction, wherein the first semiconductor chip includes a first heat source configured to consume first power, and the second semiconductor chip includes a second heat source configured to consume second power that is less than the first power, and a thermal conductivity in the horizontal direction of the first non-metal thermal conductive layer is less than a thermal conductivity of the first non-metal thermal conductive layer in the vertical direction crossing the horizontal direction, and the plurality of first thermal interfacial material patterns are spaced apart from the second thermal interfacial material patterns.

### BRIEF DESCRIPTION OF THE DRAWINGS

The above and other aspects of the present inventive concept will become more apparent by describing in detail embodiments thereof, with reference to the accompanying drawings, in which:

FIG. 1 is a diagram schematically illustrating a semiconductor package according to example embodiments of the present inventive concept;

FIG. 2 is a cross-sectional view illustrating a semiconductor package according to example embodiments of the present inventive concept;

FIGS. 3A, 3B, 3C and 3D are cross-sectional views illustrating process steps of a method of manufacturing a semiconductor device according to example embodiments of the present inventive concept;

FIG. 4 is a diagram schematically illustrating a semiconductor package according to example embodiments of the present inventive concept; and

FIG. 5 is a cross-sectional view illustrating a semiconductor package according to example embodiments of the present inventive concept.

### DETAILED DESCRIPTION OF THE EMBODIMENTS

Hereinafter, example embodiments of the present inventive concept will be described in detail with reference to the accompanying drawings. Like reference numerals may refer to like elements in the drawings and the specification, and thus, repetitive descriptions may be omitted or briefly discussed.

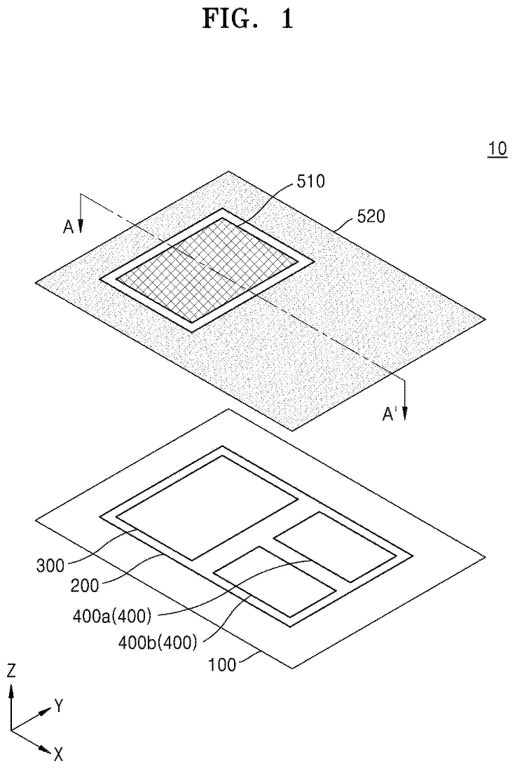

FIG. 1 is a diagram schematically illustrating a semiconductor package 10 according to example embodiments of the present inventive concept.

Referring to FIG. 1, the semiconductor package 10 may include a package substrate 100, an interposer substrate 200, a first semiconductor chip 300, a plurality of second semiconductor chips 400, a non-metal thermal conductive layer 510, and a heat-radiating member 520.

In the present specification, a direction in which the package substrate 100 extends may be a first horizontal direction X. A direction crossing the first horizontal direction X may be a second horizontal direction Y, and a direction perpendicular to a top surface of the package substrate 100 may be a vertical direction Z. In this case, the first horizontal direction X, in which the package substrate 100 extends, and the second horizontal direction Y may be defined as “horizontal directions X and Y”.

Although FIG. 1 illustrates that three semiconductor chips, which are spaced apart from one another, have been mounted in the semiconductor package 10. For example, one semiconductor chip, two semiconductor chips, or four or more semiconductor chips may be mounted in the semiconductor package 10. For example, the first semiconductor chip 300 and the second semiconductor chip 400 may be mounted in a semiconductor package 10. In addition, although the first semiconductor chip 300 is arranged in the semiconductor package 10 and two second semiconductor chips 400a and 400b are arranged to be spaced apart from the first semiconductor chip 300 in the first horizontal direction X, an arrangement relationship between the first semiconductor chip 300 and the plurality of second semiconductor chips 400 is not limited to the illustration and may have various examples.

The interposer substrate 200 may be arranged on the package substrate 100, and the first semiconductor chip 300 and the plurality of second semiconductor chips 400 may be arranged on the interposer substrate 200.

The non-metal thermal conductive layer 510 may be arranged on the first semiconductor chip 300 to overlap the first semiconductor chip 300 in the vertical direction Z, and the heat-radiating member 520 may be arranged on the plurality of second semiconductor chips 400 and may overlap the plurality of second semiconductor chips 400 in the vertical direction Z. The heat-radiating member 520 may extend in the horizontal directions X and Y from the non-metal thermal conductive layer 510. The heat-radiating member 520 may be arranged at a substantially same level as a level of the non-metal thermal conductive layer 510 in the vertical direction Z. The non-metal thermal conductive layer 510 may be arranged to cover the first semiconductor chip 300, and the heat-radiating member 520 may be arranged to cover the plurality of second semiconductor chips 400.

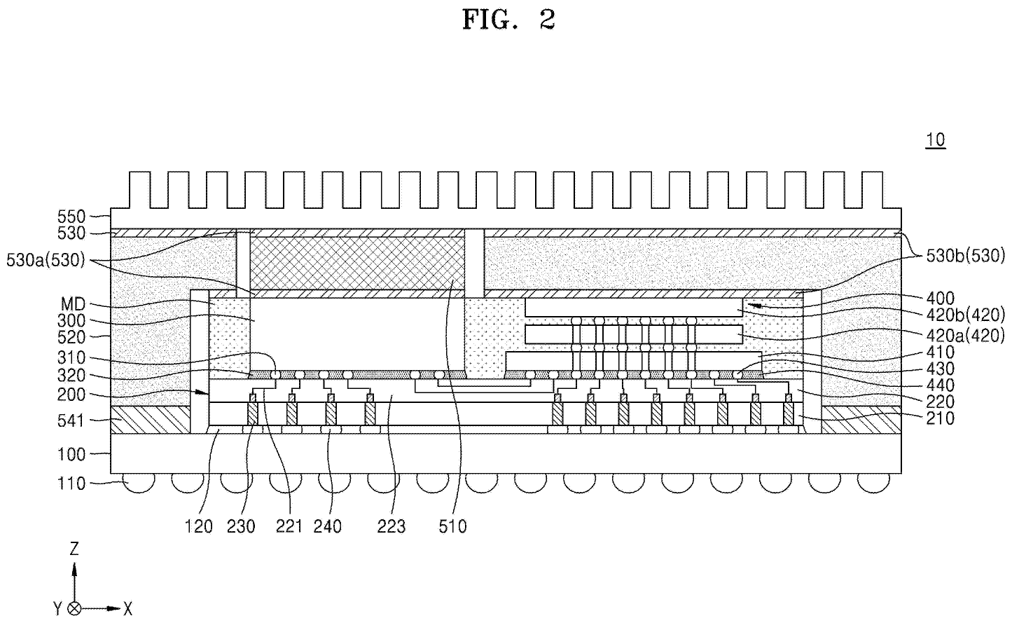

The heat-radiating member 520 may be spaced apart from the non-metal thermal conductive layer 510 in the horizontal directions X and Y and be separated from the non-metal thermal conductive layer 510. A gap may be formed between the non-metal thermal conductive layer 510 and the heat-radiating member 520, and the non-metal thermal conductive layer 520 and the heat-radiating member 520 might not be in contact with each other. Details of configurations of the non-metal thermal conductive layer 510 and the heat-radiating member 520 will be described below with reference to FIG. 2.

FIG. 2 is a cross-sectional view illustrating the semiconductor package 10 according to example embodiments of the present inventive concept.

FIG. 2 may include a cross-sectional view taken along a line A-A′ shown in FIG. 1.

Referring to FIG. 2, as described above, the semiconductor package 10 may include the package substrate 100, the interposer substrate 200, the first semiconductor chip 300, the plurality of second semiconductor chip 400, the non-metal thermal conductive layer 510, and the heat-radiating member 520.

The package substrate 100 may include a plurality of bottom pads and a plurality of top pads. The plurality of bottom pads may be arranged on a bottom surface of the package substrate 100, and external connection terminals 110 may be connected to the package substrate 100 through the plurality of bottom pads. The external connection terminal 110 may electrically connect an external device and the semiconductor package 10 to each other. In addition, the plurality of top pads may be arranged on a top surface of the package substrate 100, and the package substrate 100 may be connected to the board-interposer connection bumps 240, which is to be described later, through the plurality of top pads. The package substrate 100 and the interposer substrate 200 may be connected to each other through the board-interposer connection bumps 240.

In example embodiments of the present inventive concept, the package substrate 100 may include any one of a phenol resin, an epoxy resin, and polyimide. In example embodiments of the present inventive concept, the package substrate 100 may include a printed circuit board. For example, the package substrate 100 may include a multi-layer PCB.

The interposer substrate 200 may be arranged on the package substrate 100. In example embodiments of the present inventive concept, the semiconductor package 10 may further include a package underfill layer 120 arranged between the package substrate 100 and the interposer substrate 200. The package underfill layer 120 may be arranged to fill a gap that is between the interposer layer 200 and the package substrate 100 and cover the board-interposer connection bumps 240. For example, the package underfill layer 120 may be formed through a capillary underfill process.

The interposer substrate 200 may include a base layer 210, a redistribution structure 220, and a through electrode 230. The base layer 210 may include, for example, a semiconductor material, glass, ceramic, or plastic. In example embodiments of the present inventive concept, the base layer 210 may include a silicon wafer including silicon (Si), e.g., crystalline silicon, polycrystalline silicon, or amorphous silicon. The base layer 210 may have a substantially flat plate shape, and may include a top surface and a bottom surface that are opposite to each other.

A plurality of bottom conductive pads may be arranged on the bottom surface of the base layer 210. The plurality of bottom conductive pads may include pads arranged between the through electrode 230 and the board-interposer connection bumps 240 for forming a connection between the through electrode 230 and the board-interposer connection bumps 240. The plurality of bottom conductive pads may be spaced apart from each other on the bottom surface of the base layer 210 in the first horizontal direction (the X direction) and/or the second horizontal direction (the Y direction). The plurality of bottom conductive pads may include at least one of, for example, tungsten (W), aluminum (Al), and/or copper (Cu).

The base layer 210 may include a plurality of layers. For example, the base layer 210 may include a first base layer and a second base layer arranged on a bottom surface of the first base layer. The first base layer may include an inorganic insulating material. For example, the first base layer may include at least one of an oxide, silicon oxide, a nitride, and/or silicon nitride. The second base layer may include a material different from the material that is included in the first base layer. For example, the first base layer may include an inorganic insulating material, and the second base layer may include an organic insulating material. In example embodiments of the present inventive concept, the second base layer may include PID. In example embodiments of the present inventive concept, the second base layer may include an inorganic insulating material.

The redistribution structure 220 may be arranged on a top surface of the base layer 210. The redistribution structure 220 may include a distribution insulating layer 223, which covers the top surface of the base layer 210, and a conductive redistribution pattern 221 that is disposed in the distribution insulating layer 223. For example, the redistribution structure 220 may have a back-end-of-line (BEOL) structure.

The conductive redistribution pattern 221 may include a plurality of distribution layers, which are respectively arranged at different levels from each other and form a multi-layer structure, and a plurality of conductive vias extending in the vertical direction Z to connect the plurality of distribution layers to each other. For example, the conductive redistribution pattern 221 may include at least one of W, Al, and/or Cu.

The distribution insulating layer 223 may cover the conductive redistribution pattern 221. In example embodiments of the present inventive concept, the distribution insulating layer 223 may include an inorganic insulating material. For example, the distribution insulating layer 223 may include at least one of an oxide and/or a nitride. For example, the distribution insulating layer 223 may include at least one of silicon oxide and/or silicon nitride. In example embodiments of the present inventive concept, the distribution insulating layer 223 may include an organic insulating material. For example, the distribution insulating layer 223 may include a photo imageable dielectric (PID) material such as polyimide.

A portion of the conductive redistribution pattern 221 may be arranged on a top surface of the distribution insulating layer 223, and may function as a pad to which connection bumps 310 and 430 are attached. The connection bumps 310 and 430 electrically and physically connect each of the first semiconductor chip 300 and the second semiconductor chip 400 to the interposer substrate 200.

The through electrode 230 may electrically connect the conductive redistribution pattern 221 of the redistribution structure 220 and the board-interposer connection bump 240 to each other. The through electrode 230 may extend from the top surface of the base layer 210 to the bottom surface of the base layer 210 and penetrate the base layer 210 in the vertical direction Z. In this case, the through electrode 230 may be connected to the conductive redistribution pattern 221 and may electrically connect the conductive redistribution pattern 221 and the board-interposer connection bump 240 to each other.

In example embodiments of the present inventive concept, the through electrode 230 may include a conductive plug having a pillar shape or cylindrical shape, penetrating the base substrate 210, and a conductive barrier film having a cylinder shape with an opening and surrounding a sidewall of the conductive plug. The conductive barrier film may include at least one of, for example, Ti, TiN, Ta, TaN, Ru, Co, Mn, WN, Ni, and/or NiB, and the conductive plug may include at least one of, for example, Cu, Cu alloys such as CuSn, CuMg, CuNi, CuZn, CuPd, CuAu, CuRe, CuW, W, W alloys, Ni, Ru, and Co. A via insulating film may be disposed between the base layer 210 and the through electrode 230. The via insulating film may include, for example, an oxide film, a nitride film, a carbide film, a polymer, or combinations thereof.

The board-interposer connection bumps 240 may electrically and physically connect the interposer substrate 200 and the package substrate 100 to each other. Each of the board-interposer connection bumps 240 may have a width greater than a width of each of the connection bumps 310 and 430.

The first semiconductor chip 300 and the second semiconductor chip 400 may be mounted on the interposer substrate 200 and may be arranged in the horizontal directions X and Y on the interposer substrate 200. The first semiconductor chip 300 may include a logic chip, e.g., an application specific integrated circuit (ASIC) as a host such as a central processing unit (CPU), a graphics processing unit (GPU), and a system-on-chip (SoC). The second semiconductor chip 400 may include a memory chip, e.g., a high bandwidth memory (HBM) chip. The second semiconductor chip 400 may include a buffer die 410 functioning as a circuit and a plurality of memory dies 420 sequentially stacked on the buffer die 410. For example, the second semiconductor chip 400 may include a buffer die 410, and a first memory die 420a and a second memory die 420b, which are sequentially stacked on the buffer die 410. However, the number of memory dies that may be included in the plurality of memory dies 420 is not limited to the illustration, and for example, the second semiconductor chip 400 may also include one memory die or at least three memory dies.

In example embodiments of the present inventive concept, the first semiconductor chip 300 may include a first heat source configured to consume a first power, and the second semiconductor chip 400 may include a second heat source configured to consume a second power that is less than the first power. For example, the first power may be in a range from about 50 W to about 300 W, and the second power may be in a range from about 5 W to about 70 W. Accordingly, an amount of heat radiated from the first semiconductor chip 300 may be greater than an amount of heat radiated from the second semiconductor chip 400.

The first semiconductor chip 300 and the second semiconductor chip 400 may be mounted on the interposer substrate 200 in a flip-chip method. The first semiconductor chip 300 and the second semiconductor chip 400 may be mounted on the interposer substrate 200 through the connection bumps 310 and 430. The first semiconductor chip 300 may be electrically and physically connected to the interposer substrate 200 through the connection bumps 310, and the second semiconductor chip 400 may be electrically and physically connected to the interposer substrate 200 through the connection bumps 430. The first semiconductor chip 300 may include a first semiconductor chip pad that is disposed between the first semiconductor chip 300 and the connection bumps 310 to provide an electrical and a physical connection to the interposer substrate 200, and the second semiconductor chip 400 may include a second semiconductor chip pad that is disposed between the second semiconductor chip 400 and the connection bumps 430 to provide an electrical and physical connection to the interposer substrate 200.

Underfill layers 320 and 440 may be respectively arranged between the first semiconductor chip 300 and the interposer substrate 200 and between the second semiconductor chip 400 and the interposer substrate 200. The underfill layers 320 and 440 may respectively fill gaps that are disposed between the first semiconductor chip 300 and the interposer substrate 200 and between the second semiconductor chip 400 and the interposer substrate 200, and may at least partially surround sidewalls of the connection bumps 310 and 430. The underfill layers 320 and 440 may include, for example, an epoxy resin, an organic filler, and/or an organic filler included in the epoxy resin. The underfill layer 320 and 440 may be formed through a capillary underfill process.

The molding layer MD may at least partially surround the first semiconductor chip 300 and the second semiconductor chip 400 on a top surface of the interposer substrate 200. The molding layer MD may cover the top surface of the interposer substrate 200 and a sidewall of each of the first semiconductor chip 300 and the second semiconductor chip 400. In example embodiments of the present inventive concept, the molding layer MD may cover the sidewalls of the first semiconductor chip 300 and the second semiconductor chip 400 but might not cover the top surfaces of the first semiconductor chip 300 and the second semiconductor chip 400. In example embodiments of the present inventive concept, a top surface of the molding layer MD may be on a same plane as the top surfaces of the first semiconductor chip 300 and the second semiconductor chip 400. For example, the molding layer MD may include an epoxy resin, an inorganic filler, and/or an organic filler included in the epoxy resin. In example embodiments of the present inventive concept, the molding layer MD may include an epoxymold compound (EMC). In example embodiments of the present inventive concept, the underfill layers 320 and 440 may be omitted, and the molding layer MD may also be formed, through a molded underfill process, to further fill the gap that is between the first semiconductor chip 300 and the interposer substrate 200 and the gap that is between the second semiconductor chip 400 and the interposer substrate 200.

The non-metal thermal conductive layer 510 may be disposed on the first semiconductor chip 300. The non-metal thermal conductive layer 510 may include a non-metal heat-radiating material, e.g., graphite including a plurality of graphene layers. In example embodiments of the present inventive concept, the non-metal thermal conductive layer 510 may include graphite, and the plurality of graphene layers included in graphite may respectively extend in the vertical direction (the Z direction) and be spaced apart from one another in the horizontal direction (the X and Y directions). The non-metal heat-radiating material may have a thermal conductivity in the vertical direction Z that is higher than a thermal conductivity in the horizontal directions X and Y, and accordingly, a thermal conductivity in the vertical direction Z of the non-metal thermal conductive layer 510 may be greater than a thermal conductivity in the horizontal directions X and Y of the non-metal thermal conductive layer 510. In addition, the thermal conductivity of the non-metal thermal conductive layer 510 may be greater than a thermal conductivity of the heat-radiating member 520 that is to be described laver.

The heat-radiating member 520 may be disposed on the second semiconductor chip 400. The heat-radiating member 520 may include a heat-radiating structure such as a heat slug or a heat spreader. In example embodiments of the present inventive concept, the heat-radiating member 520 may include a material different from the material included in the non-metal thermal conductive layer 510. In example embodiments of the present inventive concept, the heat-radiating member 520 may include a flat plate or a three-dimensional body including a metal material. For example, the heat-radiating member 520 may include any one of highly thermal-conductive materials including, for example, copper, copper alloys, aluminum, aluminum alloys, steel, stainless steel, and combinations thereof.

In example embodiments of the present inventive concept, the heat-radiating member 520 may extend to cover the top surface of the second semiconductor chip 400 and the top surface of the molding layer MD that is not covered by the non-metal thermal conductive layer 510, except the top surface of the first semiconductor chip 300 that is covered by the non-metal thermal conductive layer 510. The heat-radiating member 520 may include the following: a top cover portion that covers the top surface of the molding layer MD, which is not covered by the non-metal thermal conductive layer 510, and the top surface of the second semiconductor chip 400; and a side cover portion that at least partially surrounds sidewalls of the interposer substrate 200, the first semiconductor chip 300, and the second semiconductor chip 400. The side cover portion of the heat-radiating member 520 may extend from an edge of the top cover portion of the heat-radiating member 520 to the top surface of the package substrate 100. A bottom of the side cover portion of the heat-radiating member 520 may be combined to the package substrate 100 through an adhesive member 541. According to example embodiments of the present inventive concept, the adhesive member 541 may be omitted. The heat-radiating member 520 may be configured to perform a heat-radiating function and an electromagnetic wave-blocking function, and may be electrically and physically connected to a top pad configured to provide a ground voltage to the package substrate 100.

The heat-radiating member 520 may be spaced apart from the non-metal thermal conductive layer 510 in the horizontal directions X and Y and separated from the non-metal thermal conductive layer 510. A gap may be disposed between the non-metal thermal conductive layer 510 and the heat-radiating member 520, and the non-metal thermal conductive layer 510 and the heat-radiating member 520 might not be in contact with each other. In addition, the heat-radiating member 520 may be spaced apart from the molding layer MD in the horizontal directions X and Y. For example, a gap may be between the heat-radiating member 520 and the molding layer MD.

A heat-radiating plate 550 may be arranged on the heat-radiating member 520. The heat-radiating plate 550 may include a heat sink including a pin base and a plurality of pin structures. For example, the heat-radiating plate 550 may include a pin base conformally covering the heat-radiating member 520, and may include, on the pin base, the plurality of pin structures extending in the vertical direction Z from the pin base. In example embodiments of the present inventive concept, the heat-radiating plate 550 may include a flat plate or a three-dimensional body including a metal material. The heat-radiating plate 550 may be configured to perform a heat-radiating function and an electromagnetic wave-blocking function.

A plurality of thermal interfacial material (TIM) patterns 530 may be on the first semiconductor chip 300 and the second semiconductor chip 400. The plurality of TIM patterns 530 may be between the first semiconductor chip 300 and the first non-metal thermal conductive layer 510, between the second semiconductor chip 400 and the heat-radiating member 520, between the molding layer MD and the heat-radiating member 520, between the first non-metal thermal conductive layer 510 and the heat-radiating plate 550, and between the heat-radiating member 520 and the heat-radiating plate 550.

The plurality of TIM patterns may include the following: a plurality of first TIM patterns 530a that overlap the first semiconductor chip 300 in the vertical direction Z and are spaced apart from each other in the vertical direction Z; and a plurality of second TIM patterns 530b that overlap the second semiconductor chip 400 in the vertical direction Z and are spaced apart from each other in the vertical direction Z. For example, the plurality of first TIM patterns 530a may include the following: a first TIM pattern 530a that is disposed between the top surface of the first semiconductor chip 300 and the non-metal thermal conductive layer 510; and a first TIM pattern 530a that is disposed between the non-metal thermal conductive layer 510 and the heat-radiating plate 550. In addition, the plurality of second TIM patterns 530b may include the following: a second TIM pattern 530b that is disposed between the top surface of the second semiconductor chip 400 and the heat-radiating member 520; and a second TIM pattern 530b that is disposed between the heat-radiating member 520 and the heat-radiating plate 550.

The plurality of first TIM patterns 530a may be spaced apart and separated from the plurality of second TIM patterns 530b. For example, the first TIM pattern 530a that are between the top surface of the first semiconductor chip 300 and the non-metal thermal conductive layer 510 may be spaced apart and separated from the second TIM pattern 530b that are between the top surface of the second semiconductor chip 400 and the heat-radiating member 520. In addition, the first TIM pattern 530a that are between the non-metal thermal conductive layer 510 and the heat-radiating plate 550 may be spaced apart and separated from the second TIM pattern 530b that are between the heat-radiating member 520 and the heat-radiating plate 550.

The plurality of first TIM patterns 530a may be configured to thermally and physically combine the first semiconductor chip 300 and the non-metal thermal conductive layer 510 to each other, and to thermally and physically combine the non-metal thermal conductive layer 510 and the heat-radiating plate 550 with each other. The first TIM pattern 530a, which is on the first semiconductor chip 300, may be in contact with the first semiconductor chip 300 and the non-metal thermal conductive layer 510. In addition, the first TIM pattern 530a, which is on the non-metal thermal conductive layer 510, may be in contact with the non-metal thermal conductive layer 510 and the heat-radiating plate 550. In addition, the plurality of second TIM patterns 530b may be configured to thermally and physically combine the second semiconductor chip 400 with the heat-radiating member 520, and to thermally and physically combine the heat-radiating member 520 with the heat-radiating plate 550. The second TIM pattern 530b, which is on the second semiconductor chip 400 may be in contact with the second semiconductor chip 400 and the heat-radiating member 520. In addition, the second TIM pattern 530b, which is on the heat-radiating member 520, may be in contact with the heat-radiating member 520 and the heat-radiating plate 550. By doing so, the non-metal thermal conductive layer 510 and the first semiconductor chip 300 may be thermally combined with each other, and the heat-radiating member 520 and the second semiconductor chip 400 may be thermally combined with each other. As described above, an amount of heat radiated from the first semiconductor chip 300 may be greater than an amount of heat radiated from the second semiconductor chip 400, and accordingly, a temperature of the first non-metal thermal conductive layer 510 may be greater than a temperature of the heat-radiating member 520.

The plurality of first TIM patterns 530a may extend along the top surfaces of the first semiconductor chip 300 and the non-metal thermal conductive layer 510 and cover at least a portion of each of the top surfaces of the first semiconductor chip 300 and the non-metal thermal conductive layer 510. The first TIM pattern 530a on the first semiconductor chip 300 may at least partially fill the gap that is between the first semiconductor chip 300 and the non-metal thermal conductive layer 510. The first TIM pattern 530a on the non-metal thermal conductive layer 510 may at least partially fill the gap that is between the top surface of the non-metal thermal conductive layer 510 and the heat-radiating plate 550.

The plurality of second TIM patterns 530b may extend along the top surfaces of the second semiconductor chip 400 and the heat-radiating member 520, and may cover at least a portion of the top surfaces of the second semiconductor chip 400 and the heat-radiating member 520. The second TIM pattern 530b on the second semiconductor chip 400 may at least partially fill the gap that is between the top surface of the second semiconductor chip 400 and the heat-radiating member 520. In addition, the second TIM pattern 530b may at least partially fill a portion of the gap that is between the top surface of the heat-radiating member 520 and the heat-radiating plate 550.

The plurality of first TIM patterns 530a are not limited to have a width identical to a width of the first semiconductor chip 300 or the width of the non-metal thermal conductive layer 510 in the horizontal direction X and Y, and may have a width greater or smaller than the width of the first semiconductor chip 300 and/or the width of the non-metal thermal conductive layer 510 in the horizontal direction X and Y. The plurality of second TIM patterns 530b are not limited to have a width that is identical to a width of the second semiconductor chip 400 or a width of the heat-radiating member 520 in the horizontal directions X and Y, and may have a width greater or smaller than the width of the second semiconductor chip 400 or the width of the heat-radiating member 520 in the horizontal directions X and Y. For example, a first width of the first semiconductor chip 300 in the horizontal directions X and Y may be greater or smaller than a second width of the plurality of first TIM patterns 530a in the horizontal directions X and Y. A third width of the non-metal thermal conductive layer 510 in the horizontal directions X and Y may be greater or smaller than the second width of the plurality of first TIM patterns 530a in the horizontal directions X and Y.

In example embodiments of the present inventive concept, the TIM pattern 530 may include a polymer material having an extraordinary thermal conductivity. For example, the TIM pattern 530 may include a thermally-conductive adhesive tape, a thermally-conductive grease, a thermally-conductive interface pad, a thermally-conductive adhesive, and the like, but the present inventive concept is not limited thereto.

As described above, the first power consumed by the first semiconductor chip 300 is greater than the second power consumed by the second semiconductor chip 400, and accordingly, the amount of heat radiated from the first semiconductor chip 300 may be greater than the amount of heat radiated from the second semiconductor chip 400. Therefore, thermal conduction from the first semiconductor chip 300 to the second semiconductor chip 400 may occur.

In the Comparative Example, on the first semiconductor chip 300 and the second semiconductor chip 400, the TIM pattern 530 may continuously extend to cover the top surfaces of the first semiconductor chip 300 and the second semiconductor chip 400. In addition, on the first semiconductor chip 300 and the second semiconductor chip 400, the heat-radiating member 520 may continuously extend to cover the top surfaces of the first semiconductor chip 300 and the second semiconductor chip 400. In this case, due to the TIM pattern 530 and the heat-radiating member 520, thermal conduction from the first semiconductor chip 300 to the second semiconductor chip 400 may occur.

According to example embodiments of the present inventive concept, the heat generated by the first semiconductor chip 300 may be delivered to the non-metal thermal conductive layer 510 by the first TIM pattern 530a. In this case, a thermal conductivity of the non-metal conductive layer 510 in the horizontal directions (the X direction and the Y direction) is less than a thermal conductivity of the non-metal thermal conductive layer 510 in the vertical direction Z, and accordingly, the heat delivered to the non-metal thermal conductive layer 510 may be conducted in the horizontal directions X and Y in an amount smaller than an amount of heat conducted in the vertical direction Z. Therefore, thermal conduction from the first semiconductor chip 300 to the second semiconductor chip 400 may be reduced.

In addition, the plurality of first TIM patterns 530a that are on the first semiconductor chip 300 may be spaced apart from the second TIM patterns 530 that are on the second semiconductor chip 400, and the non-metal heat-conductive layer 510 that is on the first semiconductor chip 300 may be spaced apart from the heat-radiating member 520 that is on the second semiconductor chip 400. Accordingly, thermal conduction from the first semiconductor chip 300 to the second semiconductor chip 400 may be further reduced, and ultimately, degradation in the performance of the second semiconductor chip 400 due to thermal conduction based on the first semiconductor chip 300 may be prevented.

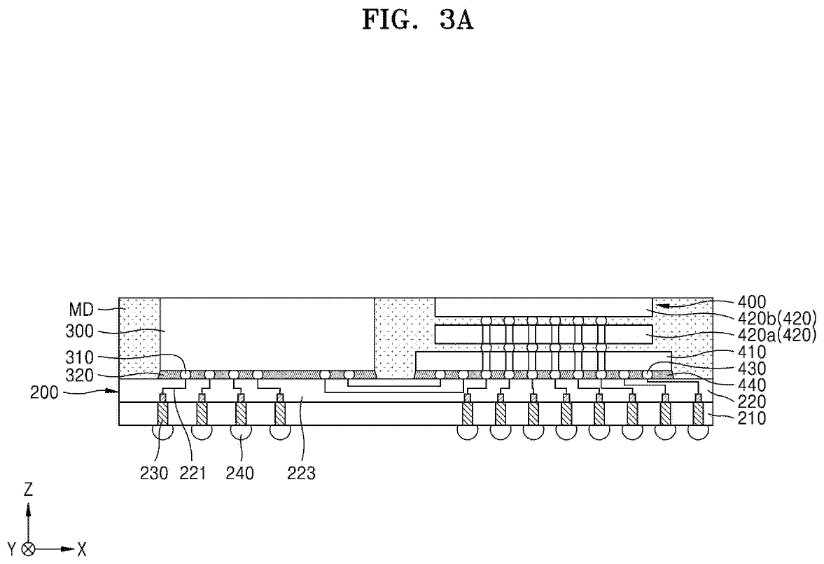

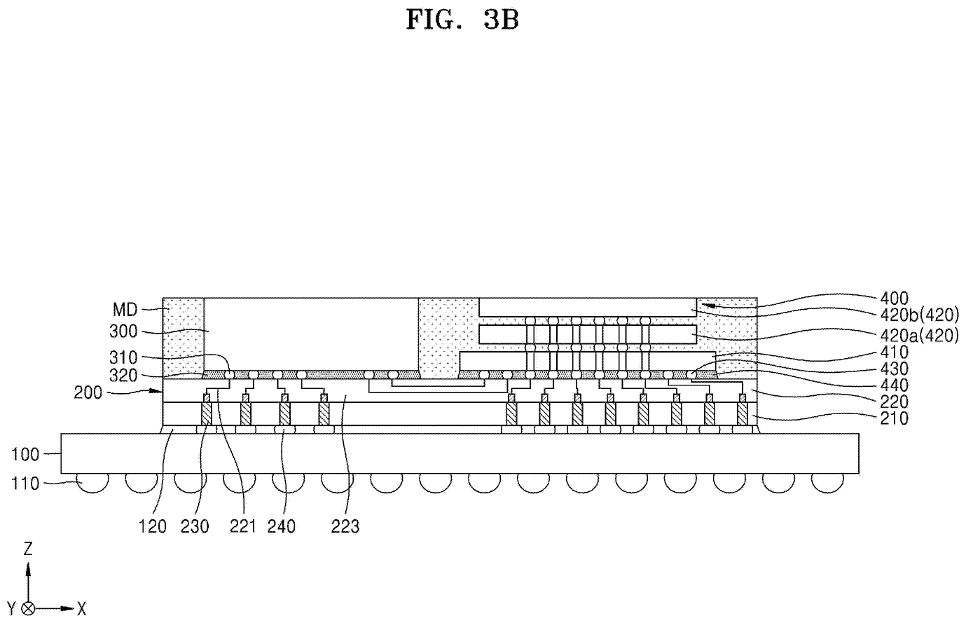

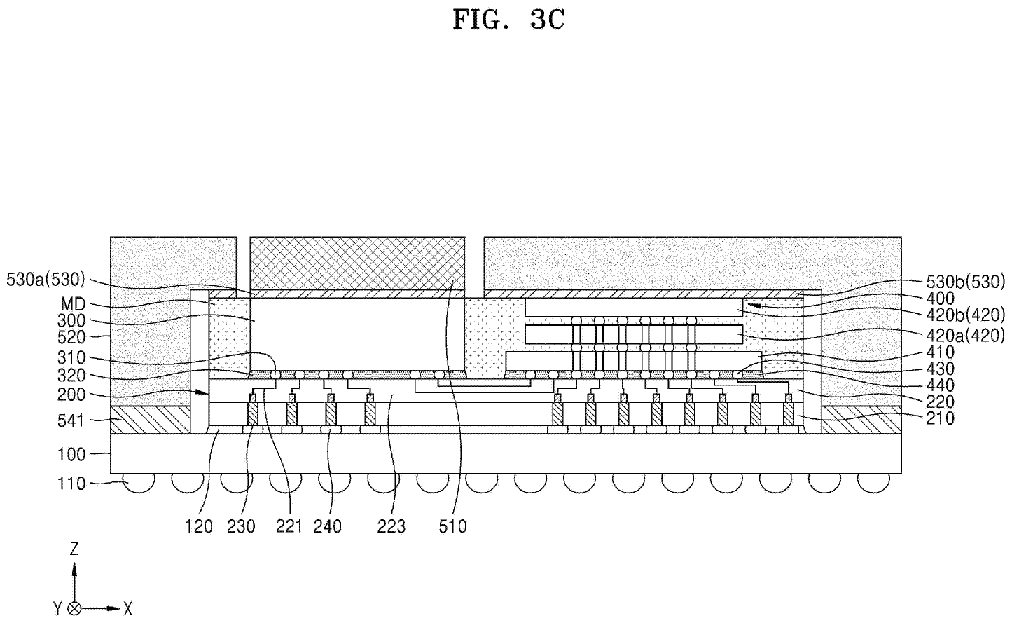

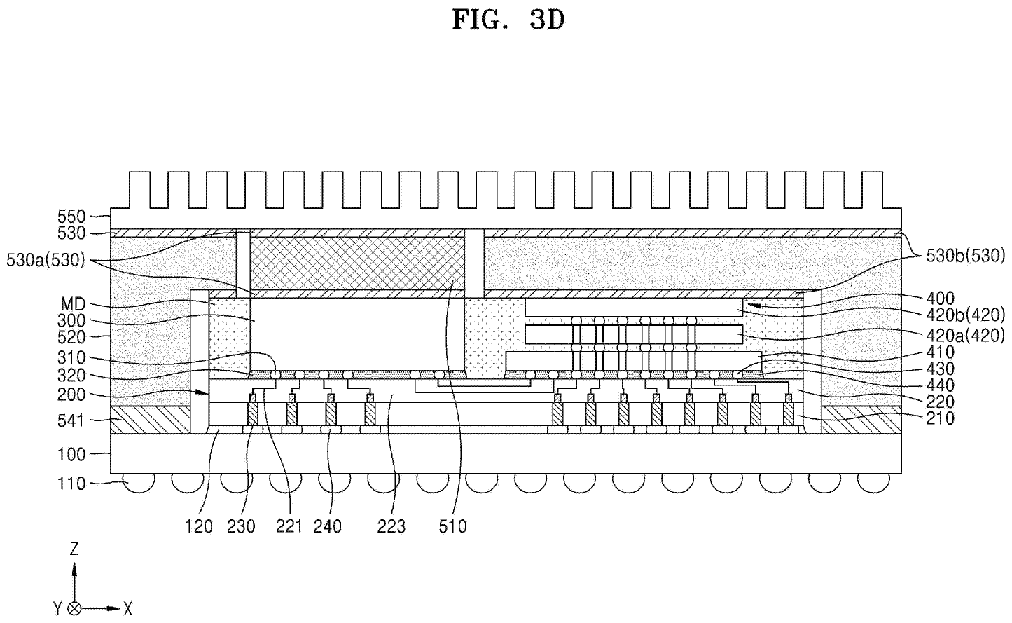

FIGS. 3A to 3D are cross-sectional views illustrating a method of manufacturing the semiconductor package 10 according to example embodiments of the present inventive concept. Hereinafter, the method of manufacturing the semiconductor package 10 shown in FIGS. 1 and 2 will be described with reference to FIGS. 3A to 3D.

Referring to FIG. 3A, prepared is a structure including the following: the interposer substrate 200; the first semiconductor chip 300 and the second semiconductor chip 400 that are mounted on the interposer substrate 200; and the molding layer MD that is disposed on the first semiconductor chip 300 and the second semiconductor chip 400, which are on the interposer substrate 200. The structure may be mounted on the package substrate 100 (see FIG. 3B). The top surfaces of the first semiconductor chip 300 and the second semiconductor chip 400 may be exposed to outside.

Referring to FIG. 3B, the structure including the following may be mounted on the package substrate 100: the interposer substrate 200; the first semiconductor chip 300 and the second semiconductor chip 400 that are mounted on the interposer substrate 200; and the molding layer MD that is disposed on the first semiconductor chip 300 and the second semiconductor chip 400, which are disposed on the interposer substrate 200. In this case, the package substrate 100 and the interposer substrate 200 may be connected to each other through the board-interposer connection bumps 240.

In example embodiments of the present inventive concept, the semiconductor package 10 may further include a package underfill layer 120 arranged between the package substrate 100 and the interposer substrate 200. The package underfill layer 120 may fill the gap that is between the interposer substrate 200 and the package substrate 100 and cover the board-interposer connection bumps 240. For example, the package underfill layer 120 may be formed through a capillary underfill process.

Referring to FIG. 3C, a thermal interfacial material (TIM) may be prepared, and the TIM pattern 530 may be formed by attaching the prepared TIM to bottom surfaces of the non-metal thermal conductive layer 510 and the heat-radiating member 520. In example embodiments of the present inventive concept, the TIM pattern 530 may include a polymer material having an extraordinary thermal conductivity. For example, the TIM pattern 530 may include a thermally-conductive adhesive tape, a thermally-conductive grease, a thermally-conductive interface pad, a thermally-conductive adhesive, and the like, but the present inventive concept is not limited thereto.

The non-metal thermal conductive layer 510 may be attached onto the first semiconductor chip 300, and the heat-radiating member 520 may be attached onto the second semiconductor chip 400. In this case, the TIM pattern 530 may be disposed between the first semiconductor chip 300 and the non-metal thermal conductive layer 510 and between the second semiconductor chip 400 and the heat-radiating member 520. The heat-radiating member 520 may extend to cover the molding layer MD that is not covered by the non-metal thermal conductive layer 510. The non-metal thermal conductive layer 510 and the heat-radiating member 520 may be respectively fixed to the first semiconductor chip 300 and the second semiconductor chip 400 by the TIM pattern 530. In addition, the heat-radiating member 520 may be connected to the package substrate 100 through an adhesive member 541. In example embodiments of the present inventive concept, the adhesive member 541 may include a conductive adhesive material such as solders.

In addition, after forming the TIM pattern 530 on the top surface of the first semiconductor chip 300 and the top surface of the second semiconductor chip 400, the non-metal thermal conductive layer 510 may be fixed onto the TIM pattern 530, which is formed on the top surface of the first semiconductor chip 300, and the heat-radiating member 520 may be fixed onto the TIM pattern 530 that is formed on the top surface of the second semiconductor chip 400.

The first TIM pattern 530a that is on the first semiconductor chip 300 and the second TIM pattern 530b that is on the second semiconductor chip 400 may be spaced apart from each other in the horizontal directions X and Y. In addition, the non-metal thermal conductive layer 510 and the heat-radiating member 520 may be spaced apart from each other in the horizontal direction X and Y.

By doing so, the non-metal thermal conductive layer 510 may be thermally combined with the first semiconductor chip 300 through the first TIM pattern 530a, and the heat-radiating member 520 may be thermally combined with the second semiconductor chip 400 through the second TIM pattern 530b.

Referring to FIG. 3D, the TIM pattern 530 may be formed by preparing the TIM and attaching the prepared TIM to the top surfaces of the non-metal thermal conductive layer 510 and the heat-radiating member 520.

The heat-radiating plate 550 may be attached onto the non-metal thermal conductive layer 510 and the heat-radiating member 520 on which the TIM patterns 530 are attached. In this case, the TIM patterns 530 may be disposed between the heat-radiating plate 550 and the non-metal thermal conductive layer 510 and between the heat-radiating plate 550 and the heat-radiating member 520, respectively. The heat-radiating plate 550 may be fixed onto the non-metal thermal conductive layer 510 and the heat-radiating member 520 through the TIM pattern 530.

The first TIM pattern 530a, which is disposed on the top surface of the non-metal thermal conductive layer 510, and the second TIM pattern 530b, which is disposed on the top surface of the heat-radiating member 520, may be formed to be spaced apart from each other in the horizontal directions (the X direction and the Y direction).

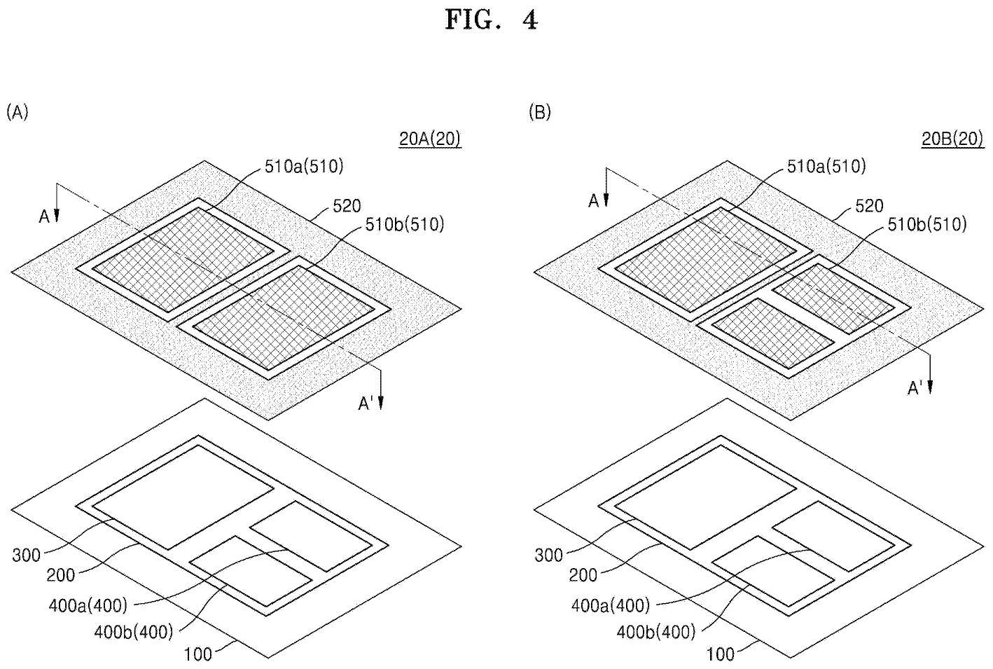

FIG. 4 is a diagram schematically illustrating a semiconductor package 20 according to example embodiments of the present inventive concept. Hereinafter, the semiconductor package 20 shown in FIG. 4 will be described mainly with regard to differences from the semiconductor package 10 described with reference to FIG. 1.

Referring to FIG. 4, the semiconductor package 20 may include the package substrate 100, the interposer substrate 200, the first semiconductor chip 300, the plurality of second semiconductor chips 400, a first non-metal thermal conductive layer 510a, a second non-metal thermal conductive layer 510b, and the heat-radiating member 520.

Although FIG. 4 illustrates that three semiconductor chips, which are spaced apart from one another, have been mounted in the semiconductor package, one semiconductor chip, two semiconductor chips, or four semiconductor chips may be mounted in the semiconductor package 20. For example, the first semiconductor chip 300 and the second semiconductor chip 400 may be mounted in a semiconductor package 10. In addition, although FIG. 4 illustrates that the first semiconductor chip 300 is arranged in the semiconductor package 10 and two second semiconductor chips 400a and 400b are spaced apart from the first semiconductor chip 300 in the first horizontal direction X, an arrangement relationship between the first semiconductor chip 300 and the second semiconductor chip 400 is not limited to the illustration and may have various examples.

Referring to (A) of FIG. 4, the first non-metal thermal conductive layer 510a may be arranged on the first semiconductor chip 300 to overlap the first semiconductor chip 300 in the vertical direction Z, and the second non-metal thermal conductive layer 510b may be arranged to overlap the plurality of second semiconductor chips 400 in the vertical direction Z. The heat-radiating member 520 may extend in the horizontal directions X and Y from the first non-metal thermal conductive layer 510a and the second non-metal thermal conductive layer 510b. The heat-radiating member 520 may be arranged at a substantially same level in the vertical direction Z as a level of the first non-metal thermal conductive layer 510a and the second non-metal thermal conductive layer 510b. The first non-metal thermal conductive layer 510a may be arranged to cover the first semiconductor chip 300, and the second non-metal thermal conductive layer 510b may be arranged to cover the plurality of second semiconductor chips 400. In example embodiments of the present inventive concept, the second non-metal thermal conductive layer 510b may extend in the horizontal directions X and Y on the plurality of second semiconductor chips 400 to cover the plurality of second semiconductor chips 400. The first non-metal thermal conductive layer 510a and the second non-metal thermal conductive layer 510b may be variously arranged, and the arrangement thereof is not limited to the arrangement shown in the accompanying drawings.

In example embodiment of the present inventive concept, when a distance between the first non-metal thermal conductive layer 510a and the second non-metal thermal conductive layer 510b is sufficiently secured, the heat-radiating member 520 may be arranged between the first non-metal thermal conductive layer 510a and the second non-metal thermal conductive layer 510b. In example embodiments of the present inventive concept, when the distance between the first non-metal thermal conductive layer 510a and the second non-metal thermal conductive layer 510b is not sufficiently secured, the heat-radiating member 520 might not be arranged between the first non-metal thermal conductive layer 510a and the second non-metal conductive layer 510b.

Referring to (B) of FIG. 4, the first non-metal thermal conductive layer 510a may be arranged to overlap the first semiconductor chip 300 in the vertical direction Z, and the plurality of second non-metal thermal conductive layers 510b may be arranged to overlap the plurality of second semiconductor chips 400 in the vertical direction Z. The first non-metal thermal conductive layer 510a may be arranged to cover the first semiconductor chip 300, and the plurality of second non-metal thermal conductive layers 510b may be arranged to respectively cover the plurality of second semiconductor chips 400. The first non-metal thermal conductive layer 510a and the plurality of second non-metal thermal conductive layers 510b may be variously arranged, and the arrangement thereof is not limited to the arrangement shown in the accompanying drawings.

In example embodiments of the present inventive concept, when a distance between the plurality of second non-metal thermal conductive 510b is sufficiently secured, the heat-radiating member 520 may be arranged between the plurality of second non-metal thermal conductive layers 510b. In example embodiments of the present inventive concept, when the distance between the second non-metal thermal conductive layers 510b are not sufficiently secured, the heat-radiating member 520 might not be arranged between the plurality of second non-metal conductive layers 510b.

Referring to (A) and (B) of FIG. 4, the second non-metal thermal conductive layer 510b may be spaced apart from the first non-metal thermal conductive layer 510a in the horizontal directions X and Y and may be spaced apart from the first non-metal thermal conductive layer 510a. A gap may be between the first non-metal thermal conductive layer 510a and the second non-metal thermal conductive layer 510b, and the first non-metal thermal conductive layer 510a and the second non-metal thermal conductive layer 510b might not be in contact with each other.

The heat-radiating member 520 may be spaced apart and separated from the first non-metal thermal conductive layer 510a and the second non-metal thermal conductive layer 510b. A gap may be disposed between the heat-radiating member 520 and the first non-metal thermal conductive layer 510a and between the heat-radiating member 520 and the second non-metal thermal conductive layer 510b. The heat-radiating member 520 and the first non-metal thermal conductive layer 510a might not be in contact with each other, and the heat-radiating member 520 and the second non-metal thermal conductive layer 510b might not be in contact with each other.

The plurality of second non-metal thermal conductive layers 510b may be spaced apart and separated from each other. A gap may be disposed between the plurality of second non-metal thermal conductive layers 510b. The plurality of second non-metal thermal conductive layers 510b might not be in contact with each other.

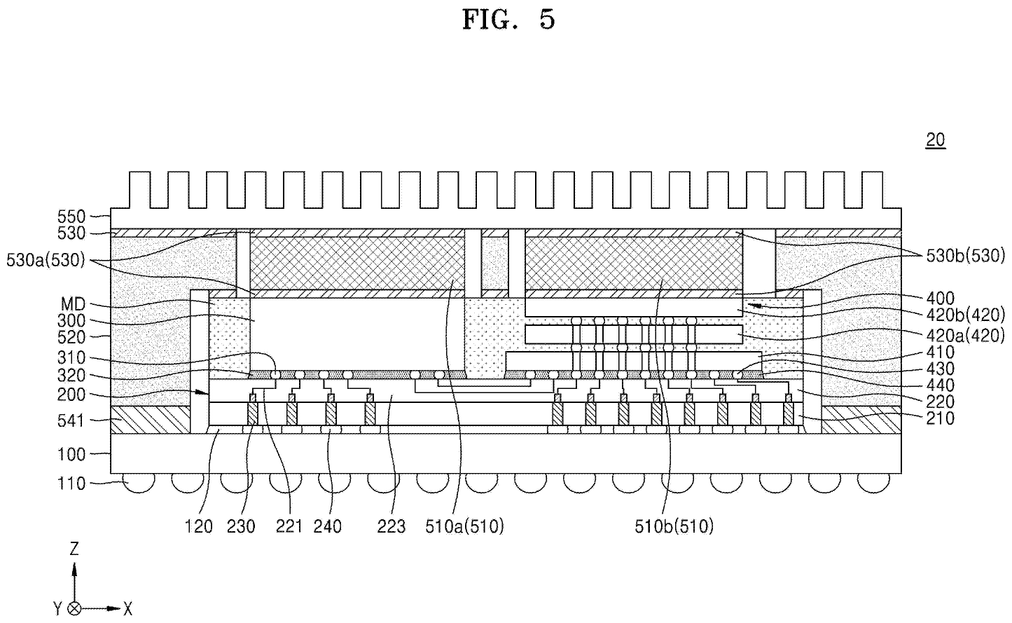

Details of configurations of the first non-metal thermal conductive layer 510a, the second non-metal thermal conductive layer 510b, and the heat-radiating member 520 will be described below with reference to FIG. 5.

FIG. 5 is a cross-sectional view illustrating a semiconductor package according to example embodiments of the present inventive concept.

FIG. 5 may include a cross-sectional view taken along a line A-A′ shown in FIG. 4. Hereinafter, the semiconductor package 20 shown in FIG. 5 will be described, mainly with regard to differences from the semiconductor package 10 described with reference to FIG. 2.

Referring to FIG. 5, the semiconductor package 20 may further include the interposer substrate 200. The first semiconductor chip 300 and the second semiconductor chip 400 may be mounted on the interposer substrate 200 and may be arranged in the horizontal directions X and Y on the interposer substrate 200. As described above with reference to FIG. 2, the first semiconductor chip 300 may include a logic chip, e.g., an ASIC as a host such as a CPU, a GPU, and an SoC. The second semiconductor chip 400 may include a memory chip, e.g., a high bandwidth memory (HBM) chip. The second semiconductor chip 400 may include the buffer die 410 functioning as a circuit and the plurality of memory dies 420 that are sequentially stacked on the buffer die 410. For example, the second semiconductor chip 400 may include the buffer die 410, and the first memory die 420a and the second memory die 420b that are sequentially stacked on the buffer die 410. However, the number of memory dies that may be included in the plurality of memory dies 420 is not limited to the illustration, and the second semiconductor chip 400 may also include one memory die or three or more memory dies.

In example embodiments of the present inventive concept, the first semiconductor chip 300 may include the first heat source that is configured to consume the first power, and the second semiconductor chip 400 may include the second heat source that is configured to consume the second power which is less than the first power. For example, the first power may be in a range from about 50 W to about 300 W, and the second power may be in a range from about 5 W to about 70 W. Accordingly, the amount of heat radiated from the first semiconductor chip 300 may be greater than the amount of heat radiated from the second semiconductor chip 400.

The first non-metal thermal conductive layer 510a may be arranged on the first semiconductor chip 300. The first non-metal thermal conductive layer 510a may include a non-metal heat-radiating material, e.g., graphite including a plurality of graphene layers. In example embodiments of the present inventive concept, the non-metal thermal conductive layer 510 may include graphite, and the plurality of graphene layers included in graphite may respectively extend in the vertical direction Z and be spaced apart from one another in the horizontal direction X and Y. The non-metal heat-radiating material may have the thermal conductivity in the vertical direction Z that is higher than the thermal conductivity in the horizontal directions X and Y, and accordingly, the thermal conductivity in the vertical direction Z of the first non-metal thermal conductive layer 510a may be greater than the thermal conductivity in the horizontal directions X and Y of the first non-metal thermal conductive layer 510a. In addition, the thermal conductivity of the first non-metal thermal conductive layer 510a may be higher than the thermal conductivity of the heat-radiating member 520 that is to be described later.

The second non-metal thermal conductive layer 510b may be arranged on the second semiconductor chip 400. The second non-metal thermal conductive layer 510b may include a non-metal heat-radiating material, for example, a material identical to the material included in the first non-metal thermal conductive layer 510a. The non-metal heat-radiating material included in the second non-metal thermal conductive layer 510b may be identical to the non-metal heat-radiating material that is included in the first non-metal thermal conductive layer 510a. The thermal conductivity in the vertical direction of the non-metal heat-radiating material may be greater than the thermal conductivity in the horizontal directions X and Y of the non-metal heat-radiating material, and accordingly, the thermal conductivity in the vertical direction Z of the second non-metal thermal conductive layer 510b may be greater than the thermal conductivity in the horizontal directions X and Y of the second non-metal thermal conductive layer 510b. In addition, the thermal conductivity of the second non-metal thermal conductive layer 510b may be greater than the thermal conductivity of the heat-radiating member 520 that is to be described later.

The heat-radiating member 520 may be arranged to planarly surround the first non-metal thermal conductive layer 510a and the second non-metal thermal conductive layer 510b. The heat-radiating member 520 may include a heat-radiating structure such as a heat slug or a heat spreader. In example embodiments of the present inventive concept, the heat-radiating member 520 may include a material different from the materials included in the first non-metal thermal conductive layer 510a and the second non-metal thermal conductive layer 510b. In example embodiments of the present inventive concept, the heat-radiating member 520 may include a flat plate or a three-dimensional body including a metal material. For example, the heat-radiating member 520 may include any one of highly thermal-conductive materials including copper, copper alloys, aluminum, aluminum alloys, steel, stainless steel, and combinations thereof.

In example embodiments of the present inventive concept, the heat-radiating member 520 may extend to cover the top surface of the molding layer MD that is not covered by the first non-metal thermal conductive layer 510a and the second non-metal thermal conductive layer 510b. In example embodiment of the present inventive concept, when a distance between the first non-metal thermal conductive layer 510a and the second non-metal thermal conductive layer 510b is sufficiently secured, the heat-radiating member 520 may be arranged between the first non-metal thermal conductive layer 510a and the second non-metal thermal conductive layer 510b. In example embodiments of the present inventive concept, when the distance between the first non-metal thermal conductive layer 510a and the second non-metal thermal conductive layer 510b is not sufficiently secured, the heat-radiating member 520 might not be arranged between the first non-metal thermal conductive layer 510a and the second non-metal conductive layer 510b.

The heat-radiating member 520 may include the following: the top cover portion covering the top surface of the molding layer MD, which is not covered by the first non-metal thermal conductive 510a and the second non-metal thermal conductive layer 510b; and the side cover portion that surrounds the sidewalls of the interposer substrate 200, the first semiconductor chip 300, and the second semiconductor chip 400. The side cover portion of the heat-radiating member 520 may extend from an edge of the top cover portion of the heat-radiating member 520 to the top surface of the package substrate 100. A bottom of the side cover portion of the heat-radiating member 520 may be combined to the package substrate 100 through the adhesion member 541. According to embodiments of the present inventive concept, the adhesion member 541 may be omitted. The heat-radiating member 520 may be configured to perform a heat-radiating function and an electromagnetic wave-blocking function, and may be electrically and physically connected to a top pad configured to provide a ground voltage to the package substrate 100.

The heat-radiating member 520 may be spaced apart from the first non-metal thermal conductive layer 510a in the horizontal directions X and Y and might not be connected to the first non-metal thermal conductive layer 510a. In addition, the heat-radiating member 520 may be spaced apart from the second non-metal thermal conductive layer 510b in the horizontal directions X and Y and might not be connected to the second non-metal thermal conductive layer 510b. For example, a gap may be between the heat-radiating member 520 and the first non-metal thermal conductive layer 510a and between the heat-radiating member 520 and the second non-metal thermal conductive layer 510b. The heat-radiating member 520 might not be in contact with the first non-metal thermal conductive layer 510a and the second non-metal thermal conductive layer 510b. The heat-radiating member 520 may be spaced apart from the molding layer MD in the horizontal directions X and Y. For example, a gap may be between the heat-radiating member 520 and the molding layer MD.

The heat-radiating plate 550 may be arranged on the heat-radiating member 520. The heat-radiating plate 550 may include a heat sink including a pin base and a plurality of pin structures.

The TIM patterns 530 may be disposed on the first semiconductor chip 300 and the second semiconductor chip 400. The plurality of TIM patterns 530 may be between the first semiconductor chip 300 and the first non-metal thermal conductive layer 510a, between the second semiconductor chip 400 and the second non-metal thermal conductive layer 510b, between the molding layer MD and the heat-radiating member 520, between the first non-metal thermal conductive layer 510a and the heat-radiating plate 550, between the second non-metal thermal conductive layer 510b and the heat-radiating plate 550, and between the heat-radiating member 520 and the heat-radiating plate 550.

The plurality of TIM patterns may include the following: the plurality of first TIM patterns 530a that overlap the first semiconductor chip 300 in the vertical direction Z and are spaced apart from each other in the vertical direction Z; and the plurality of second TIM patterns 530b that overlap the second semiconductor chip 400 in the vertical direction Z and are spaced apart from each other in the vertical direction Z. For example, the plurality of first TIM patterns 530a may include the following: the first TIM pattern 530a that is disposed between the top surface of the first semiconductor chip 300 and the non-metal thermal conductive layer 510; and the first TIM pattern 530a that is disposed between the non-metal thermal conductive layer 510 and the heat-radiating plate 550. For example, the plurality of second TIM patterns 530b may include the following: the second TIM pattern 530b that is disposed between a top surface of the second semiconductor chip 400 and the second non-metal thermal conductive layer 510b; and the second TIM pattern 530b that is disposed between the second non-metal thermal conductive layer 510b and the heat-radiating plate 550.

The plurality of first TIM patterns 530a may be spaced apart and separated from the plurality of second TIM patterns 530b. For example, the first TIM pattern 530a that is between the top surface of the first semiconductor chip 300 and the non-metal thermal conductive layer 510 may be spaced apart and separate from the second TIM pattern 530b that is between the top surface of the second semiconductor chip 400 and the second non-metal thermal conductive layer 510b. In addition, the first TIM pattern 530a, which is between the non-metal thermal conductive layer 510 and the heat-radiating plate 550, may be spaced apart and separate from the second TIM pattern 530b that is between the second non-metal thermal conductive layer 510b and the heat-radiating plate 550.

The plurality of TIM patterns 530a may be configured to thermally and physically combine the first semiconductor chip 300 and the first non-metal thermal conductive layer 510a with each other and thermally and physically combine the first non-metal thermal conductive layer 510a and the heat-radiating plate 550 with each other. The first TIM pattern 530a, which is on the first semiconductor chip 300, may be in contact with the first semiconductor chip 300 and the first non-metal thermal conductive layer 510a. In addition, the first TIM pattern 530a on the first non-metal thermal conductive layer 510a may be in contact with the first non-metal thermal conductive layer 510a and the heat-radiating plate 550. In addition, the plurality of second TIM patterns 530b may be configured to thermally and physically combine the second semiconductor chip 400 with the second non-metal thermal conductive layer 510b and thermally and physically combine the second non-metal thermal conductive layer 510b with the heat-radiating plate 550. The second TIM pattern 530b, which is on the second semiconductor chip 400, may be in contact with the second semiconductor chip 400 and the second non-metal thermal conductive layer 510b. In addition, the second TIM pattern 530b, which is on the second non-metal thermal conductive layer 510b, may be in contact with the second non-metal thermal conductive layer 510b and the heat-radiating plate 550. By doing so, the first non-metal thermal conductive layer 510a and the first semiconductor chip 300 may be thermally combined with each other, and the second non-metal thermal conductive layer 510b and the second semiconductor chip 400 may be thermally combined with each other. As described above, the amount of heat radiated from the first semiconductor chip 300 may be greater than the amount of heat radiated from the second semiconductor chip 400, and accordingly, the temperature of the first non-metal thermal conductive layer 510a may be greater than a temperature of the second non-metal thermal conductive layer 510b.

The plurality of first TIM patterns 530a may respectively extend along the top surfaces of the first semiconductor chip 300 and the first non-metal thermal conductive layer 510a and cover at least a portion of each of the top surfaces of the first semiconductor chip 300 and the first non-metal thermal conductive layer 510a. The first TIM pattern 530a, which is on the first semiconductor chip 300, may at least partially fill the gap that is between the top surface of the first semiconductor chip 300 and the first non-metal thermal conductive layer 510a. The first TIM pattern 530a, which is on the first non-thermal conductive layer 510a, may at least partially fill the gap that is between the first non-thermal conductive layer 510a and the heat-radiating plate 550.

The plurality of second TIM patterns 530b may extend along the top surface of each of the second semiconductor chip 400 and the second non-metal thermal conductive layer 510b and cover at least a portion of the top surface of each of the second semiconductor chip 400 and the second non-metal thermal conductive layer 510b. The second TIM pattern 530b, which is on the second semiconductor chip 400, may at least partially fill the gap that is between the top surface of the second semiconductor chip 400 and the second non-metal thermal conductive layer 510b. The second TIM pattern 530b, which is on the second non-metal thermal conductive layer 510b, may at least partially fill the gap that is between the top surface of the second non-metal thermal conductive layer 510b and the heat-radiating plate 550.

The plurality of first TIM patterns 530a are not limited to have a width identical to a width of the first semiconductor chip 300 or a width of the first non-metal thermal conductive layer 510a in the horizontal directions X and Y and may have a width greater or smaller than the width of the first semiconductor chip 300 and/or the width of the first non-metal thermal conductive layer 510a in the horizontal directions X and Y. The plurality of second TIM patterns 530b are not limited to have a width that is identical to a width of the second semiconductor chip 300 or a width of the second non-metal thermal conductive layer 510b in the horizontal directions X and Y, and may have a width greater or smaller than the width of the second semiconductor chip 400 and/or the width of the second non-metal thermal conductive layer 510b in the horizontal directions X and Y. For example, the first width of the first semiconductor chip 300 in the horizontal directions X and Y may be greater or smaller than a second width of the plurality of first TIM patterns 530a in the horizontal directions X and Y. A third width of the first non-metal thermal conductive layer 510a in the horizontal directions X and Y may be greater or less than the second width of the plurality of first TIM patterns 530a in the horizontal directions X and Y. For example, the first width of the second semiconductor chip 400 in the horizontal directions X and Y may be greater or less than the second width of the plurality of second TIM patterns 530b in the horizontal directions X and Y. The third width of the second non-metal thermal conductive layer 510b in the horizontal directions X and Y may be greater or smaller than the second width of the plurality of second TIM patterns 530b in the horizontal directions X and Y.

In example embodiments of the present inventive concept, the TIM pattern 530 may include a polymer material having a thermal conductivity, as described above with reference to FIG. 2. For example, the TIM pattern 530 may include a thermally-conductive adhesive tape, a thermally-conductive grease, a thermally-conductive interface pad, a thermally-conductive adhesive, and the like, but the present inventive concept is not limited thereto.

As described above, the first power consumed by the first semiconductor chip 300 is greater than the second power consumed by the second semiconductor chip 400, and therefore, the amount of heat radiated from the first semiconductor chip 300 may be greater than the amount of heat radiated from the second semiconductor chip 400, and thermal conduction from the first semiconductor chip 300 to the second semiconductor chip 400 may occur.

In the Comparative Example, on the first semiconductor chip 300 and the second semiconductor chip 400, the TIM pattern 530 may continuously extend to cover the top surfaces of the first semiconductor chip 300 and the second semiconductor chip 400. In addition, on the first semiconductor chip 300 and the second semiconductor chip 400, the heat-radiating member 520 may continuously extend to cover the top surfaces of the first semiconductor chip 300 and the second semiconductor chip 400. In this case, thermal conduction from the first semiconductor chip 300 to the second semiconductor chip 400 may occur due to the TIM pattern 530 and the heat-radiating member 520.

According to example embodiments of the present inventive concept, the heat generated from the first semiconductor chip 300 may be delivered to the first non-metal thermal conductive layer 510a by the first TIM pattern 530a. In addition, the heat generated from the second semiconductor chip 400 may be delivered to the second non-metal thermal conductive layer 510b by the second TIM pattern 530b. In this case, the thermal conductivity in the horizontal directions X and Y of the first non-metal thermal conductive layer 510a is less than the thermal conductivity in the vertical direction Z of the first non-metal thermal conductive layer 510a, and accordingly, an amount of the heat delivered to the first non-metal thermal conductive layer 510a in the horizontal directions X and Y may be less than an amount of heat delivered to the first non-metal thermal conductive layer 510a in the vertical direction Z. The thermal conductivity in the horizontal directions X and Y of the second non-metal thermal conductive layer 510b is less than the thermal conductivity in the vertical direction Z of the second non-metal thermal conductive layer 510b, and accordingly, the amount of heat delivered to the second non-metal thermal conductive layer 510b in the horizontal directions X and Y may be less than the amount of heat delivered to the second non-metal thermal conductive layer 510b in the vertical direction Z. Therefore, thermal conduction from the first semiconductor chip 300 to the second semiconductor chip 400 may be reduced.

In addition, the plurality of first TIM patterns 530a that are on the first semiconductor chip 300 may be separated from the plurality of second TIM patterns that are on the second semiconductor chip, and the first non-metal thermal conductive layer 510a that is on the first semiconductor chip 300 may be separated from the second non-metal thermal conductive layer 510b that is on the second semiconductor chip 510b. In addition, the first non-metal thermal conductive layer 510a and the second non-metal thermal conductive layer 510b may each be separated from the heat-radiating member 520. Accordingly, thermal conduction from the first semiconductor chip 300 to the second semiconductor chip 400 may be further reduced, and ultimately, degradation in the performance of the second semiconductor chip 400 due to thermal conduction with the first semiconductor chip 300 may be prevented.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a first semiconductor chip disposed on a package substrate;
a second semiconductor chip adjacent to the first semiconductor chip in a horizontal direction and disposed on the package substrate;
a plurality of first thermal interfacial material patterns overlapping the first semiconductor chip in a vertical direction;
a plurality of second thermal interfacial material patterns overlapping the second semiconductor chip in the vertical direction; and
a first non-metal thermal conductive layer disposed between the plurality of first thermal interfacial material patterns,
wherein the plurality of first thermal interfacial materials are spaced apart from the plurality of second thermal interfacial materials in the horizontal direction, and
a thermal conductivity of the first non-metal thermal conductive layer in the horizontal direction is lower than a thermal conductivity of the first non-metal thermal conductive layer in the vertical direction.

2. The semiconductor package of claim 1,
further comprising a heat-radiating member disposed between the plurality of second thermal interfacial material patterns,
wherein the heat-radiating member is spaced apart from the first non-metal thermal conductive layer in the horizontal direction.

3. The semiconductor package of claim 2, wherein a thermal conductivity of the first non-metal thermal conductive layer is greater than a thermal conductivity of the heat-radiating member.

4. The semiconductor package of claim 2, wherein the heat-radiating member comprises a substantially flat surface and a metal material.

5. The semiconductor package of claim 1, wherein the first semiconductor chip comprises a first heat source configured to consume first power, and
the second semiconductor chip comprises a second heat source configured to consume second power that is less than the first power.

6. The semiconductor package of claim 1, wherein the first non-metal thermal conductive layer comprises graphite.

7. The semiconductor package of claim 1,
further comprising a second non-metal thermal conductive layer disposed between the plurality of second thermal interfacial material patterns,
wherein the second non-metal thermal conductive layer is spaced apart from the first non-metal thermal conductive layer in the horizontal direction.

8. The semiconductor package of claim 7, further comprising a heat-radiating member at least partially surrounding the first non-metal thermal conductive layer and the second non-metal thermal conductive layer.

9. The semiconductor package of claim 8, wherein the heat-radiating member is spaced apart from the first non-metal thermal conductive layer and the second non-metal thermal conductive layer.

10. The semiconductor package of claim 8, wherein each of a thermal conductivity of the first non-metal thermal conductive layer and a thermal conductivity of the second non-metal thermal conductive layer is greater than a thermal conductivity of the heat-radiating member.

11. The semiconductor package of claim 7, wherein a thermal conductivity of the second non-metal thermal conductive layer in the horizontal direction is less than a thermal conductivity of the second non-metal thermal conductive layer in the vertical direction.

12. A semiconductor package comprising:
a first semiconductor chip disposed on a package substrate;
a second semiconductor chip disposed adjacent to the first semiconductor chip in a horizontal direction;
a plurality of first thermal interfacial material patterns overlapping the first semiconductor chip in a vertical direction;
a plurality of second thermal interfacial material patterns overlapping the second semiconductor chip in the vertical direction; and
a first non-metal thermal conductive layer disposed between the plurality of first thermal interfacial material patterns,
wherein the first semiconductor chip comprises a first heat source configured to consume first power, and
the second semiconductor chip comprises a second heat source configured to consume second power that is less than the first power, and
a thermal conductivity of the first non-metal thermal conductive layer in the horizontal direction is less than a thermal conductivity of the first non-metal conductive layer in the vertical direction crossing the horizontal direction.

13. The semiconductor package of claim 12, wherein the plurality of first thermal interfacial material patterns are spaced apart from the plurality of second thermal interfacial material patterns in the horizontal direction.

14. The semiconductor package of claim 12,
further comprising a heat-radiating member disposed between the plurality of second thermal interfacial material patterns,
wherein the heat-radiating member comprises a material that is different from a material of the first non-metal thermal conductive layer, and
the heat-radiating member is spaced apart from the first non-metal thermal conductive layer in the horizontal direction.

15. The semiconductor package of claim 14,
wherein the plurality of first thermal interfacial material patterns respectively contact the first semiconductor chip and the first non-metal thermal conductive layer, and
the plurality of second thermal interfacial material patterns respectively contact the second semiconductor chip and the heat-radiating member.

16. The semiconductor package of claim 12,
further comprising a second non-metal thermal conductive layer disposed between the plurality of second thermal interfacial material patterns,
wherein the second non-metal thermal conductive layer is spaced apart from the first non-metal thermal conductive layer in the horizontal direction.

17. The semiconductor package of claim 16,
wherein the plurality of first thermal interfacial material patterns respectively contact the first semiconductor chip and the first non-metal thermal conductive layer, and
the plurality of second thermal interfacial material patterns respectively contact the second semiconductor chip and the second non-metal thermal conductive layer.

18. A semiconductor comprising:
a package substrate;
an interposer substrate disposed on the package substrate;
a first semiconductor chip mounted on the interposer substrate;
a second semiconductor chip mounted on the interposer substrate and spaced apart from the first semiconductor chip in a horizontal direction;
a plurality of first thermal interfacial material patterns overlapping the first semiconductor chip in a vertical direction;
a plurality of second thermal interfacial material patterns overlapping the second semiconductor chip in the vertical direction; and
a first non-metal thermal conductive layer disposed between the plurality of first thermal interfacial material patterns in the vertical direction,
wherein the first semiconductor chip comprises a first heat source configured to consume first power, and
the second semiconductor chip comprises a second heat source configured to consume second power that is less than the first power, and
a thermal conductivity in the horizontal direction of the first non-metal thermal conductive layer is less than a thermal conductivity of the first non-metal thermal conductive layer in the vertical direction crossing the horizontal direction, and
the plurality of first thermal interfacial material patterns are spaced apart from the second thermal interfacial material patterns.

19. The semiconductor package of claim 18, wherein the first non-metal thermal conductive layer comprises graphite.

20. The semiconductor package of claim 19,
further comprising a heat-radiating member disposed between the plurality of second thermal interfacial material patterns,
wherein the heat-radiating member is spaced apart from the first non-metal thermal conductive layer and comprises a metal material.
